(19) United States
(12) Patent Application Publication
(10) Pub. No.: US 2025/0385654 A1
(43) Pub. Date: Dec. 18, 2025

(54) PIEZOELECTRIC DEVICE FREQUENCY SHIFT GEOMETRY TUNING

(71) Applicant: RF360 Singapore Pte. Ltd., Republic Plaza (SG)

(72) Inventors: Johannes KOERBER, Munich (DE); Mikhail PASKO, Munich (DE); Matthias HONAL, Munich (DE); Matthias KNAPP, Munich (DE); Nicolas RAAB, München (DE)

(21) Appl. No.: 18/745,899

(22) Filed: Jun. 17, 2024

(51) Int. Cl. H03H 3/10; H03H 9/02; H03H 9/145; H03H 9/25

(52) U.S. Cl. CPC H03H 3/10; H03H 9/02834; H03H 9/145; H03H 9/25

(57) ABSTRACT

Aspects include devices and methods for frequency tuned piezoelectric devices. In some aspects, a device includes a piezoelectric layer, a metallization layer comprising an interdigital transducer formed on a top surface of the piezoelectric layer, where the interdigital transducer comprises interleaved electrode fingers, a dielectric layer formed over the piezoelectric layer and the metallization layer, and where a first dielectric layer thickness over top surfaces of the interleaved electrode fingers is thinner than a second dielectric layer thickness over the piezoelectric layer between adjacent electrode fingers of the interleaved electrode fingers.

### TECHNICAL FIELD

This disclosure relates generally to wireless transceivers and, more specifically, to piezoelectric devices frequency shift tuned using milling to adjust device geometries.

### BACKGROUND

Electronic devices use radio-frequency (RF) signals to communicate information. Such RF signals are used by electronic devices to enable users to talk with friends, download information, share pictures, remotely control household devices, receive global positioning information, among others. To transmit or receive the RF signals within a given frequency band, an electronic device may use filters to pass signals within the frequency band and to suppress (e.g., attenuate) jammers or noise having frequencies outside of the frequency band. It can be challenging, however, to design a filter that provides filtering for high-frequency applications, including those that utilize frequencies above 2 gigahertz (GHz) with good performance.

### SUMMARY

Aspects are disclosed for piezoelectric devices with a resonance frequency shift tuned using milling.

In some aspects, the techniques described herein relate to an electroacoustic apparatus including: a piezoelectric layer; a metallization layer including an interdigital transducer formed on a top surface of the piezoelectric layer, wherein the interdigital transducer includes interleaved electrode fingers; and a dielectric layer formed over the piezoelectric layer and the metallization layer, wherein a first dielectric layer thickness over top surfaces of the interleaved electrode fingers is thinner than a second dielectric layer thickness over the piezoelectric layer between adjacent electrode fingers of the interleaved electrode fingers.

In some aspects, the techniques described herein relate to an electroacoustic apparatus, wherein the dielectric layer includes Aluminum Oxide (Al2O3).

In some aspects, the techniques described herein relate to an electroacoustic apparatus, wherein the dielectric layer includes silicon nitride Silicon Nitride (Si3N4).

In some aspects, the techniques described herein relate to an electroacoustic apparatus, wherein the top surfaces are rounded such that the interleaved electrode fingers each have rounded top surfaces opposite the top surface of the piezoelectric layer

In some aspects, the techniques described herein relate to an electroacoustic apparatus, wherein the dielectric layer is formed using atomic layer deposition.

In some aspects, the techniques described herein relate to an electroacoustic apparatus, wherein the electroacoustic apparatus is a resonator within a wireless communication filter.

In some aspects, the techniques described herein relate to an electroacoustic apparatus, further including control circuitry and an antenna coupled to the interdigital transducer for wireless communications.

In some aspects, the techniques described herein relate to an electroacoustic apparatus, wherein a ratio of the second dielectric layer thickness to the first dielectric layer thickness is greater than one.

In some aspects, the techniques described herein relate to an electroacoustic apparatus, wherein the dielectric layer forms a curved bowl shape between the first electrode finger and the second electrode layer.

In some aspects, the techniques described herein relate to an electroacoustic device including: a piezoelectric layer having a top surface; a first electrode finger having a bottom surface on the top surface of the piezoelectric layer, a top surface opposite the top surface of the piezoelectric layer, and first electrode sidewalls; a second electrode finger parallel to the first electrode finger having a bottom surface on the top surface of the piezoelectric layer, a top surface opposite the top surface of the piezoelectric layer, and second electrode sidewalls; and a dielectric layer formed over the piezoelectric layer, the first electrode finger, and the second electrode finger, wherein a first dielectric layer thickness over the top surface of the first electrode finger is less than a second dielectric layer thickness over the piezoelectric layer between the first electrode finger and the second electrode finger, and wherein a sidewall thickness of the dielectric layer along a first sidewall of the first electrode finger increases along the first sidewall from the top surface to the bottom surface of the first electrode finger.

In some aspects, the techniques described herein relate to an electroacoustic device, wherein the top surface of the first electrode finger and the top surface of the second electrode finger have a rounded top from a milling process.

In some aspects, the techniques described herein relate to an electroacoustic device, wherein the dielectric layer forms a curved bowl shape between the first electrode finger and the second electrode layer.

In some aspects, the techniques described herein relate to an electroacoustic device, wherein the milling process is a gas cluster ion beam milling process.

In some aspects, the techniques described herein relate to an electroacoustic device, wherein the dielectric layer is formed as a uniform thickness dielectric layer which is adjusted via milling to generate the first dielectric layer thickness and the second dielectric layer thickness.

In some aspects, the techniques described herein relate to an electroacoustic device, wherein the dielectric layer includes hafnium oxide (HfO2).

In some aspects, the techniques described herein relate to an electroacoustic device, wherein the dielectric layer includes yttrium oxide (Y2O3).

In some aspects, the techniques described herein relate to an electroacoustic device, wherein a sidewall thickness of the dielectric layer at the bottom surface of the first electrode finger is greater than the second dielectric layer thickness.

In some aspects, the techniques described herein relate to a method of manufacturing a surface acoustic wave (SAW) resonator, the method including: forming a piezoelectric layer; forming a metallization layer on a top surface of the metallization layer; forming an interdigital transducer in the metallization layer, wherein the interdigital transducer includes interleaved electrode fingers separated from adjacent electrode fingers by gaps along the top surface of the metallization layer between the adjacent electrode fingers; forming a dielectric layer over the piezoelectric layer and the interdigital transducer; and milling the dielectric layer to generate a frequency shift in a resonance of the SAW resonator greater than 20 megahertz (MHz).

In some aspects, the techniques described herein relate to a method, further including: forming the piezoelectric layer, the interdigital transducer, and the dielectric layer as part of a wafer including a plurality of SAW resonators; sampling operating frequencies of the plurality of SAW resonators in different positions on the wafer; wherein milling includes a gas cluster ion beam milling process performed on the wafer based on the sampled operating frequencies to determine milling dwell times matched to the different positions on the wafer; and separating the wafer into different devices.

In some aspects, the techniques described herein relate to a method, wherein top surfaces of the interleaved electrode fingers have a rounded top from a milling process, wherein the dielectric layer forms a curved bowl shape between the adjacent electrode fingers from the milling process, and wherein a ratio of a second dielectric layer thickness between the adjacent electrode finger to a first dielectric layer thickness on the top surfaces is greater than one due to the milling process.

### BRIEF DESCRIPTION OF DRAWINGS

FIG. 1 illustrates an example operating environment for an acoustic filter with geometry tuning in accordance with aspects described herein.

FIG. 2 illustrates an example wireless transceiver including surface-acoustic-wave filters with geometry tuning in accordance with aspects described herein.

FIG. 3A illustrates an example implementation of a portion of a surface-acoustic-wave filter that can be implemented with geometry tuning in accordance with aspects described herein.

FIG. 3B illustrates a two-dimensional cross-section view of the example implementation of the portion of the surface-acoustic wave filter of FIG. 3A.

FIG. 4A illustrates an example implementation of a portion of a surface-acoustic-wave filter that can be implemented with geometry tuning in accordance with aspects described herein.

FIG. 4B illustrates a two-dimensional cross-section view of the portion of the surface-acoustic-wave filter of FIG. 4A.

FIG. 5A illustrates aspects of a piezoelectric device with geometry tuning in accordance with aspects described herein.

FIG. 5B illustrates aspects of a piezoelectric device with geometry tuning in accordance with aspects described herein.

FIG. 5C illustrates aspects of a piezoelectric device with geometry tuning in accordance with aspects described herein.

FIG. 5D illustrates aspects of a piezoelectric device with geometry tuning in accordance with aspects described herein.

FIG. 6A illustrates aspects of a piezoelectric device with geometry tuning in accordance with aspects described herein.

FIG. 6B illustrates aspects of a piezoelectric device with geometry tuning in accordance with aspects described herein.

FIG. 6C illustrates aspects of a piezoelectric device with geometry tuning in accordance with aspects described herein.

FIG. 7A illustrates aspects of a piezoelectric device with geometry tuning in accordance with aspects described herein.

FIG. 7B illustrates aspects of a piezoelectric device with geometry tuning in accordance with aspects described herein.

FIG. 7C illustrates aspects of a piezoelectric device with geometry tuning in accordance with aspects described herein.

FIG. 8A illustrates aspects of a wafer including piezoelectric devices that can be tested and tuned using geometry tuning in accordance with aspects described herein.

FIG. 8B illustrates a performance chart of piezoelectric devices tuned using geometry tuning in accordance with aspects described herein.

FIG. 8C illustrates a performance chart of piezoelectric devices tuned using prior oxygen trimming tuning for comparison with the performance chart of FIG. 7B that illustrates performance of piezoelectric devices tuned using geometry tuning in accordance with aspects described herein.

FIG. 9 is a flow diagram illustrating an example process for manufacturing a surface-acoustic-wave filter using geometry tuning in accordance with aspects described herein.

### DETAILED DESCRIPTION

To transmit or receive radio-frequency (RF) signals within a given frequency band, an electronic device may use filters to pass signals within the frequency band and to suppress (e.g., attenuate) jammers or noise having frequencies outside of the frequency band. Electroacoustic devices (e.g., “acoustic filters”) can be used to filter high-frequency signals in many applications, such as those with frequencies that are greater than 100 megahertz (MHz). An acoustic filter is tuned to pass certain frequencies (e.g., frequencies within its passband) and attenuate other frequencies (e.g., frequencies that are outside of its passband). Using a piezoelectric material as a vibrating medium, the acoustic filter operates by transforming an electrical signal wave that is propagating along an electrical conductor into an acoustic wave (e.g., an acoustic signal wave) that forms across the piezoelectric material. The acoustic wave is then converted back into an electrical filtered signal. The acoustic filter can include an electrode structure that transforms or converts between the electrical and acoustic waves.

The acoustic wave propagates across the piezoelectric material at a velocity having a magnitude that is significantly less than that of the propagation velocity of the electrical wave. Generally, the magnitude of the propagation velocity of a wave is proportional to a size of a wavelength of the wave. Consequently, after conversion of the electrical signal wave into the acoustic wave, the wavelength of the acoustic wave is significantly smaller than the wavelength of the electrical signal wave. The resulting smaller wavelength of the acoustic wave enables filtering to be performed using a smaller filter device. This permits acoustic filters to be used in space-constrained devices, including portable electronic devices such as cellular phones.

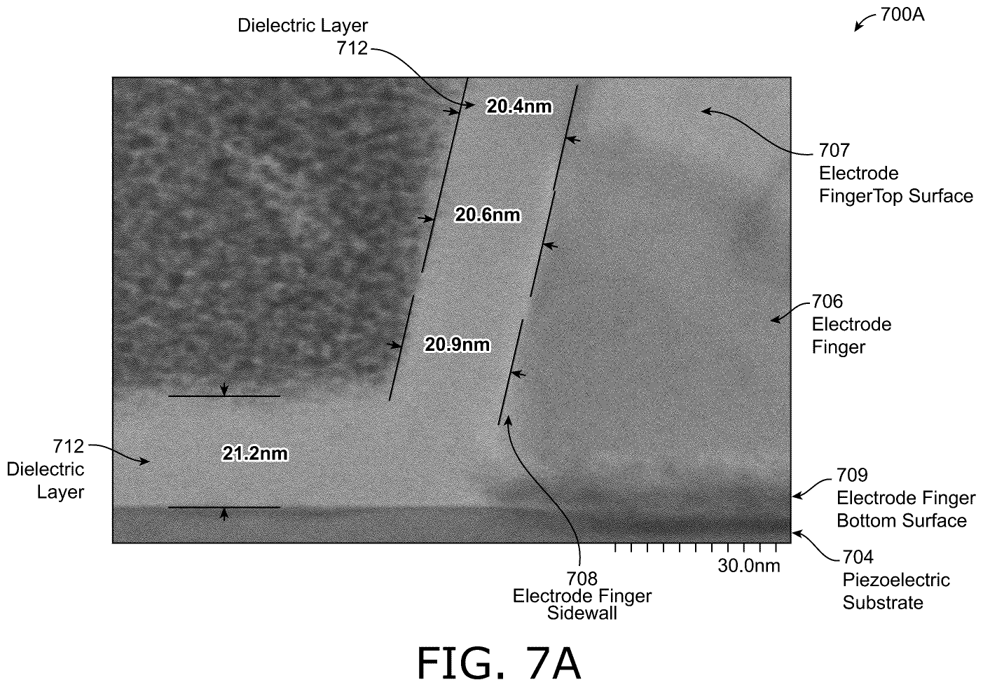

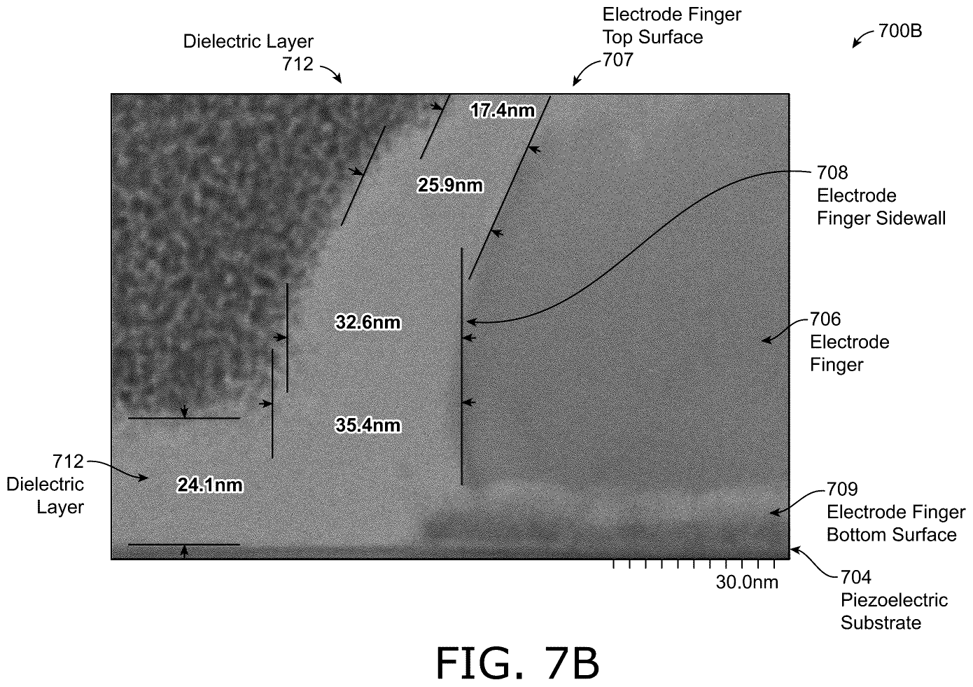

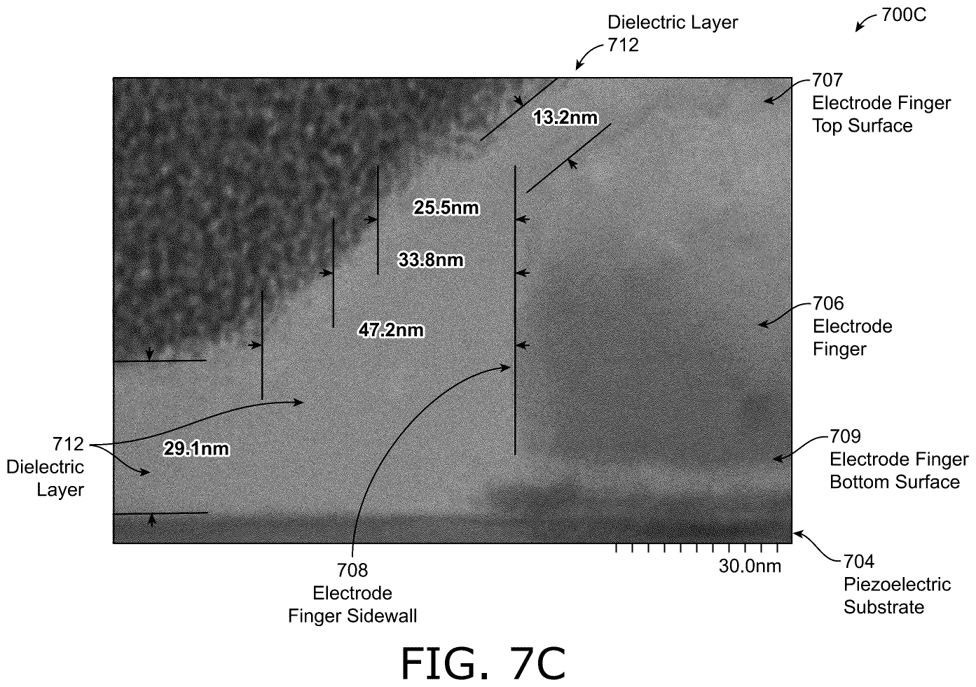

Design of acoustic filters, including those that utilize frequencies above 2 gigahertz (GHz), that can provide filtering for high-frequency applications while maintaining target performance levels can involve trade-offs and challenges. For example, such devices are fabricated on a wafer that can contain thousands or tens of thousands of electroacoustic resonators per wafer. Production tolerances during fabrication of such a wafer can result in performance variations across the wafer. For example, FIG. 7A (described in more detail below) illustrates resonance frequency variations in individual devices based on positions within a wafer.

Use of oxygen (O2) beams for trimming devices to adjust frequency resonance variations is one known way of compensating for such variations. Oxygen trimming, however, has a limited trimming window, and can result in device failure when the trimming levels approach the limits of the maximum frequency adjustments possible due to device damage that can occur during the trimming process (e.g., destruction of electrode fingers in an interdigital transducer, complete removal of a dielectric layer, etc.)

Aspects described herein involve the use of a milling process to modify device geometries in ways that provide additional device improvements beyond previously known tuning methods. The described geometry tuning in accordance with aspects described herein can provide a larger usable tuning window, and an associated higher frequency shift for matching or shifting device frequencies in a wafer.

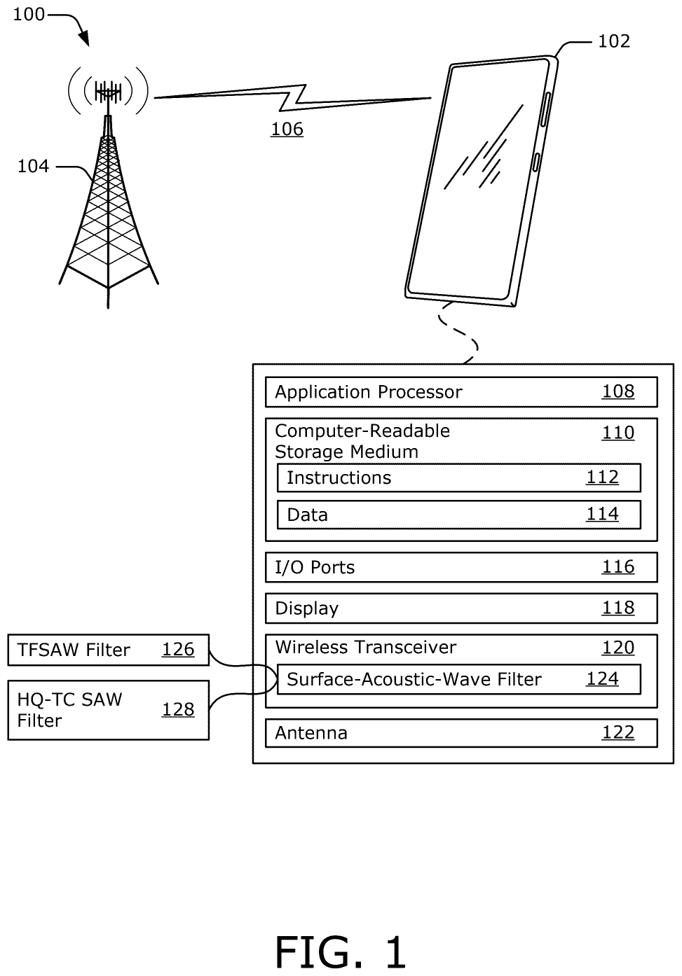

FIG. 1 illustrates an example environment 100 for a piezoelectric device that can be tuned in accordance with aspects described herein. In the environment 100, a computing device 102 communicates with a base station 104 through a wireless communication link 106 (e.g., a wireless link). In this example, the computing device 102 is depicted as a smartphone. However, the computing device 102 can be implemented as any suitable computing or electronic device, such as a modem, a cellular base station, a broadband router, an access point, a cellular phone, a gaming device, a navigation device, a media device, a laptop computer, a desktop computer, a tablet computer, a wearable computer, a server, a network-attached storage (NAS) device, a smart appliance or other internet of things (IoT) device, a medical device, a vehicle-based communication system, a radar, a radio apparatus, and so forth.

The base station 104 communicates with the computing device 102 via the wireless link 106, which can be implemented as any suitable type of wireless link. Although depicted as a tower of a cellular network, the base station 104 can represent or be implemented as another device, such as a satellite, a server device, a terrestrial television broadcast tower, an access point, a peer-to-peer device, a mesh network node, and so forth. Therefore, the computing device 102 may communicate with the base station 104 or another device via a wireless connection.

The wireless link 106 can include a downlink of data or control information communicated from the base station 104 to the computing device 102, an uplink of other data or control information communicated from the computing device 102 to the base station 104, or both a downlink and an uplink. The wireless link 106 can be implemented using any suitable communication protocol or standard, such as 2nd-generation (2G), 3rd-generation (3G), 4th-generation (4G), or 5th-generation (5G) cellular; IEEE 802.11 (e.g., Wi-Fi®); IEEE 802.15 (e.g., Bluetooth®); IEEE 802.16 (e.g., WiMAX®); and so forth. In some implementations, the wireless link 106 may wirelessly provide power and the base station 104 or the computing device 102 may comprise a power source.

As shown, the computing device 102 includes an application processor 108 and a computer-readable storage medium 110 (CRM 110). The application processor 108 can include any type of processor, such as a multi-core processor, which executes processor-executable code stored by the CRM 110. The CRM 110 can include any suitable type of data storage media, such as volatile memory (e.g., random access memory (RAM)), non-volatile memory (e.g., Flash memory), optical media, magnetic media (e.g., disk), and so forth. In the context of this disclosure, the CRM 110 is implemented to store instructions 112, data 114, and other information of the computing device 102, and thus does not include transitory propagating signals or carrier waves.

The computing device 102 can also include input/output ports 116 (I/O ports 116) and a display 118. The I/O ports 116 enable data exchanges or interaction with other devices, networks, or users. The I/O ports 116 can include serial ports (e.g., universal serial bus (USB) ports), parallel ports, audio ports, infrared (IR) ports, user interface ports such as a touchscreen, and so forth. The display 118 presents graphics of the computing device 102, such as a user interface associated with an operating system, program, or application. Alternatively or additionally, the display 118 can be implemented as a display port or virtual interface, through which graphical content of the computing device 102 is presented.

A wireless transceiver 120 of the computing device 102 provides connectivity to respective networks and other electronic devices connected therewith. The wireless transceiver 120 can facilitate communication over any suitable type of wireless network, such as a wireless local area network (WLAN), peer-to-peer (P2P) network, mesh network, cellular network, wireless wide-area-network (WWAN), and/or wireless personal-area-network (WPAN). In the context of the example environment 100, the wireless transceiver 120 enables the computing device 102 to communicate with the base station 104 and networks connected therewith. However, the wireless transceiver 120 can also enable the computing device 102 to communicate “directly” with other devices or networks.

The wireless transceiver 120 includes circuitry and logic for transmitting and receiving communication signals via an antenna 122. Components of the wireless transceiver 120 can include amplifiers, switches, mixers, analog-to-digital converters, filters, and so forth for conditioning the communication signals (e.g., for generating or processing signals). The wireless transceiver 120 can also include logic to perform in-phase/quadrature (I/Q) operations, such as synthesis, encoding, modulation, decoding, demodulation, and so forth. In some cases, components of the wireless transceiver 120 are implemented as separate transmitter and receiver entities. Additionally or alternatively, the wireless transceiver 120 can be realized using multiple or different sections to implement respective transmitting and receiving operations (e.g., separate transmit and receive chains). In general, the wireless transceiver 120 processes data and/or signals associated with communicating data of the computing device 102 over the antenna 122.

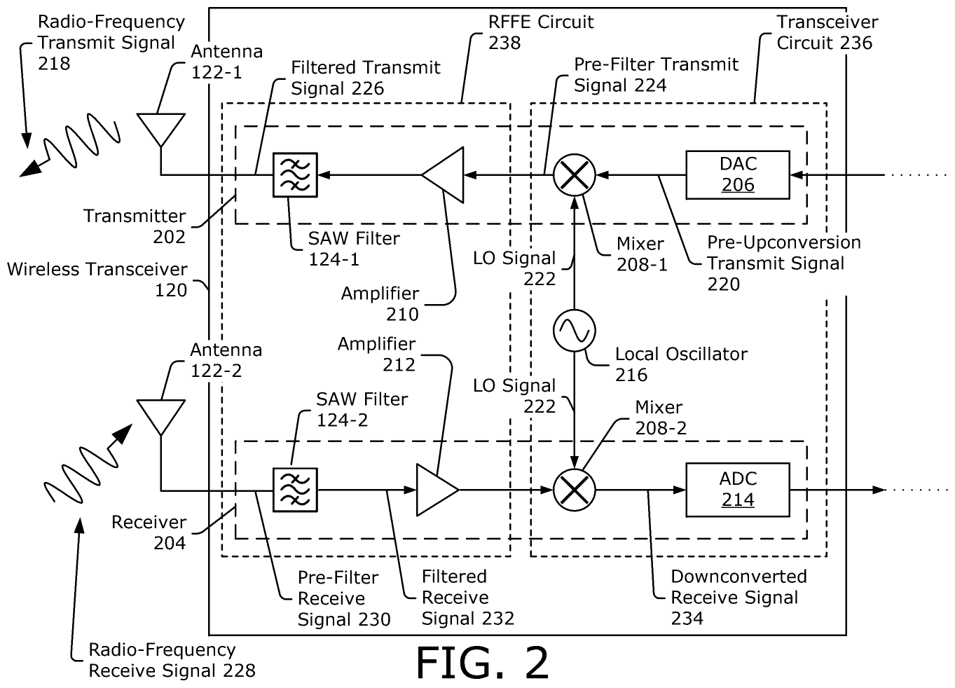

In the example shown in FIG. 1, the wireless transceiver 120 includes at least one surface-acoustic-wave filter 124 (e.g., an electroacoustic device, SAW device, etc.). In some implementations, the wireless transceiver 120 includes multiple surface-acoustic-wave filters 124, which can be arranged in series, in parallel, in a ladder structure, in a lattice structure, or some combination thereof. The surface-acoustic-wave filter 124 can be a thin-film surface-acoustic-wave filter or a high-quality temperature-compensated surface-acoustic-wave filter (HQ-TC SAW filter). The surface-acoustic-wave filter 124 can be manufactured using site-selective piezoelectric-layer trimming to suppress spurious modes. The surface-acoustic-wave filter 124 is further described with respect to FIG. 2.

FIG. 2 illustrates an example wireless transceiver 120. In the depicted configuration, the wireless transceiver 120 includes a transmitter 202 and a receiver 204, which are respectively coupled to a first antenna 122-1 and a second antenna 122-2. In other implementations, the transmitter 202 and the receiver 204 can be connected to a same antenna through a duplexer (not shown), such as a transmit-receive switch or a circulator. The transmitter 202 is shown to include at least one digital-to-analog converter 206 (DAC 206), at least one first mixer 208-1, at least one amplifier 210 (e.g., a power amplifier), and at least one first surface-acoustic-wave filter 124-1. The receiver 204 includes at least one second surface-acoustic-wave filter 124-2, at least one amplifier 212 (e.g., a low-noise amplifier), at least one second mixer 208-2, and at least one analog-to-digital converter 214 (ADC 214). The first mixer 208-1 and the second mixer 208-2 are coupled to a local oscillator 216. Although not explicitly shown, the digital-to-analog converter 206 of the transmitter 202 and the analog-to-digital converter 214 of the receiver 204 can be coupled to the application processor 108 (of FIG. 1) or another processor associated with the wireless transceiver 120 (e.g., a modem).

In some implementations, the wireless transceiver 120 is implemented using multiple circuits, such as a transceiver circuit 236 and a radio-frequency front-end (RFFE) circuit 238. As such, the components that form the transmitter 202 and the receiver 204 are distributed across these circuits. As shown in FIG. 2, the transceiver circuit 236 includes the digital-to-analog converter 206 of the transmitter 202, the mixer 208-1 of the transmitter 202, the mixer 208-2 of the receiver 204, and the analog-to-digital converter 214 of the receiver 204. In other implementations, the digital-to-analog converter 206 and the analog-to-digital converter 214 can be implemented on another separate circuit that includes the application processor 108 or the modem. The radio-frequency front-end circuit 238 includes the amplifier 210 of the transmitter 202, the surface-acoustic-wave filter 124-1 of the transmitter 202, the surface-acoustic-wave filter 124-2 of the receiver 204, and the amplifier 212 of the receiver 204.

During transmission, the transmitter 202 generates a radio-frequency transmit signal 218, which is transmitted using the antenna 122-1. To generate the radio-frequency transmit signal 218, the digital-to-analog converter 206 provides a pre-upconversion transmit signal 220 to the first mixer 208-1. The pre-upconversion transmit signal 220 can be a baseband signal or an intermediate-frequency signal. The first mixer 208-1 upconverts the pre-upconversion transmit signal 220 using a local oscillator (LO) signal 222 provided by the local oscillator 216. The first mixer 208-1 generates an upconverted signal, which is referred to as a pre-filter transmit signal 224. The pre-filter transmit signal 224 can be a radio-frequency signal and include some spurious (e.g., unwanted) frequencies, such as a harmonic frequency. The amplifier 210 amplifies the pre-filter transmit signal 224 and passes the amplified pre-filter transmit signal 224 to the first surface-acoustic-wave filter 124-1.

The first surface-acoustic-wave filter 124-1 filters the amplified pre-filter transmit signal 224 to generate a filtered transmit signal 226. As part of the filtering process, the first surface-acoustic-wave filter 124-1 attenuates the one or more spurious frequencies within the pre-filter transmit signal 224. The transmitter 202 provides the filtered transmit signal 226 to the antenna 122-1 for transmission. The transmitted filtered transmit signal 226 is represented by the radio-frequency transmit signal 218.

During reception, the antenna 122-2 receives a radio-frequency receive signal 228 and passes the radio-frequency receive signal 228 to the receiver 204. The second surface-acoustic-wave filter 124-2 accepts the received radio-frequency receive signal 228, which is represented by a pre-filter receive signal 230. The second surface-acoustic-wave filter 124-2 filters any spurious frequencies within the pre-filter receive signal 230 to generate a filtered receive signal 232. Example spurious frequencies can include jammers or noise from the external environment.

The amplifier 212 of the receiver 204 amplifies the filtered receive signal 232 and passes the amplified filtered receive signal 232 to the second mixer 208-2. The second mixer 208-2 downconverts the amplified filtered receive signal 232 using the local oscillator signal 222 to generate the downconverted receive signal 234. The analog-to-digital converter 214 converts the downconverted receive signal 234 into a digital signal, which can be processed by the application processor 108 or another processor associated with the wireless transceiver 120 (e.g., the modem).

FIG. 2 illustrates one example configuration of the wireless transceiver 120. Other configurations of the wireless transceiver 120 can support multiple frequency bands and share an antenna 122 across multiple transceivers. One of ordinary skill in the art can appreciate the variety of other configurations for which surface-acoustic-wave filters 124 may be included. For example, the surface-acoustic-wave filters 124 can be integrated within duplexers or diplexers of the wireless transceiver 120. Example implementations of the surface-acoustic-wave filter 124-1 or 124-2 are further described with respect to FIGS. 3-1 and 3-2.

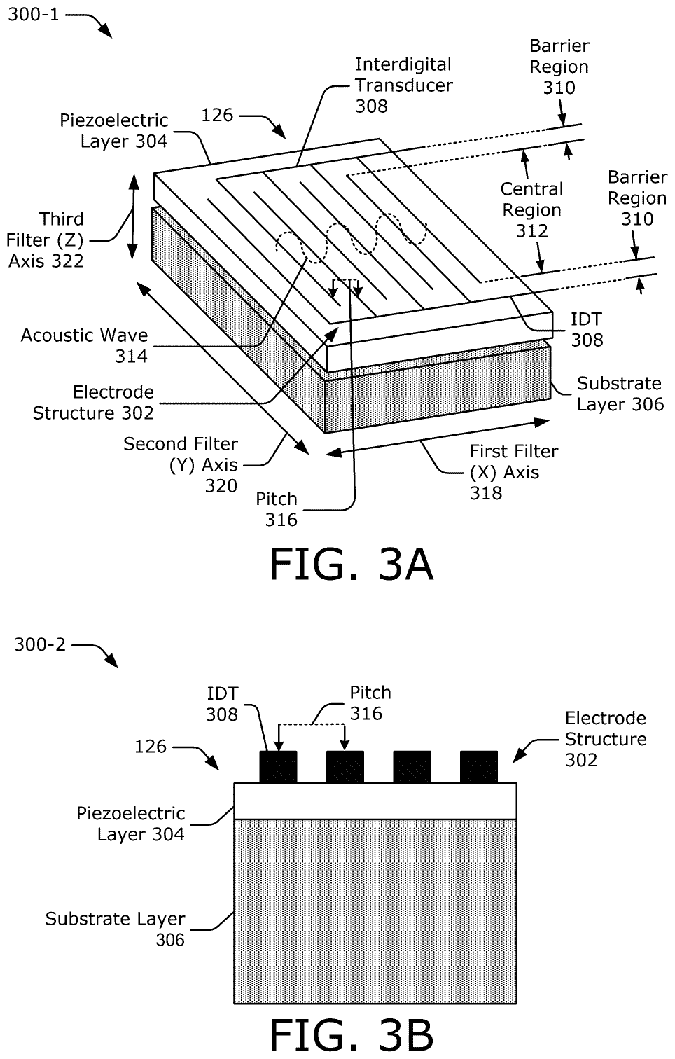

FIGS. 3A and 3B illustrate an example implementation of the thin-film surface-acoustic-wave filter 126 with site-selective piezoelectric-layer trimming. A three-dimensional perspective view 300-1 of the thin-film surface-acoustic-wave filter 126 is shown in FIG. 3A, and a two-dimensional cross-section view 300-2 of the thin-film surface-acoustic-wave filter 126 is shown at in FIG. 3B.

The thin-film surface-acoustic-wave filter 126 includes at least one electrode structure 302, at least one piezoelectric layer 304 (e.g., piezoelectric material), and at least one substrate layer 306. The electrode structure 302 is implemented using conductive material, such as metal, and can include one or more layers. The one or more layers can include one or more metal layers and can optionally include one or more adhesion layers. As an example, the metal layers can be composed of aluminum (Al), copper (Cu), silver (Ag), gold (Au), tungsten (W), or some combination or doped version thereof. The adhesion layers can be composed of chromium (Cr), titanium (Ti), molybdenum (Mo), or some combination thereof.

The electrode structure 302 can include one or more interdigital transducers 308. The interdigital transducer 308 converts an electrical signal into an acoustic wave and converts the acoustic wave into a filtered electrical signal. Although not explicitly shown, the electrode structure 302 can also include two or more reflectors. In an example implementation, the interdigital transducer 308 is arranged between two reflectors (not shown), which reflect the acoustic wave back towards the interdigital transducer 308.

In the depicted configuration shown in the two-dimensional cross-section view 300-2, the piezoelectric layer 304 is disposed between the electrode structure 302 and the substrate layer 306. The piezoelectric layer 304 can be implemented using a variety of different materials that exhibit piezoelectric properties (e.g., can transfer mechanical energy into electrical energy or electrical energy into mechanical energy). Example types of material include lithium niobate (LiNbO₃), lithium tantalate (LiTaO₃), or quartz. In general, the material that forms the piezoelectric layer 304 has a crystalline structure. This crystalline structure is defined by an ordered arrangement of particles (e.g., atoms, ions, or molecules).

The substrate layer 306 includes one or more sublayers that can support passivation, temperature compensation, power handling, mode suppression, and so forth. As an example, the substrate layer 306 can include at least one compensation layer, at least one charge-trapping layer, at least one support layer, or some combination thereof. These sublayers can be considered part of the substrate layer 306 or their own separate layers. Example types of material that can form one or more sublayers within the substrate layer 306 include silicon dioxide (SiO₂), polysilicon (poly-Si) (e.g., polycrystalline silicon or multicrystalline silicon), amorphous silicon, silicon nitride (SiN), silicon oxynitride (SiON), aluminums nitride (AlN), non-conducting material (e.g., silicon (Si), doped silicon, sapphire, silicon carbide (SiC), fused silica, glass, diamond), or some combination thereof.

In the three-dimensional perspective view 300-1, the interdigital transducer 308 is shown to have two comb-shaped electrode structures with fingers (e.g., electrode fingers) extending from two busbars (e.g., conductive segments or rails) towards each other in an interleaved fashion (e.g., interleaved electrode fingers. The fingers are arranged in an interlocking or interleaved manner in between the two busbars of the interdigital transducer 308 (e.g., arranged in an interdigitated manner). In other words, the fingers connected to a first busbar extend towards a second busbar but do not connect to the second busbar. As such, there is a barrier region 310 between the ends of these fingers and the second busbar. Likewise, fingers connected to the second busbar extend towards the first busbar but do not connect to the first busbar. There is therefore a barrier region 310 between the ends of these fingers and the first busbar.

In the direction along the busbars, there is an overlap region including a central region 312 where a portion of one finger overlaps with a portion of an adjacent finger. This central region 312, including the overlap, may be referred to as the aperture, track, or active region where electric fields are produced between fingers to cause an acoustic wave 314 to form at least in this region of the piezoelectric layer 304.

A physical periodicity of the fingers is referred to as a pitch 316 of the interdigital transducer 308. The pitch 316 may be indicated in various ways. For example, in certain aspects, the pitch 316 may correspond to a magnitude of a distance between consecutive fingers of the interdigital transducer 308 in the central region 312. This distance may be defined, for example, as the distance between center points of each of the fingers. The distance may be generally measured between a right (or left) edge of one finger and the right (or left) edge of an adjacent finger when the fingers have uniform widths. In certain aspects, an average of distances between adjacent fingers of the interdigital transducer 308 may be used for the pitch 316. The frequency at which the piezoelectric layer 304 vibrates is a main-resonance frequency of the electrode structure 302. The frequency is determined at least in part by the pitch 316 of the interdigital transducer 308 and other properties of the thin-film surface-acoustic-wave filter 126.

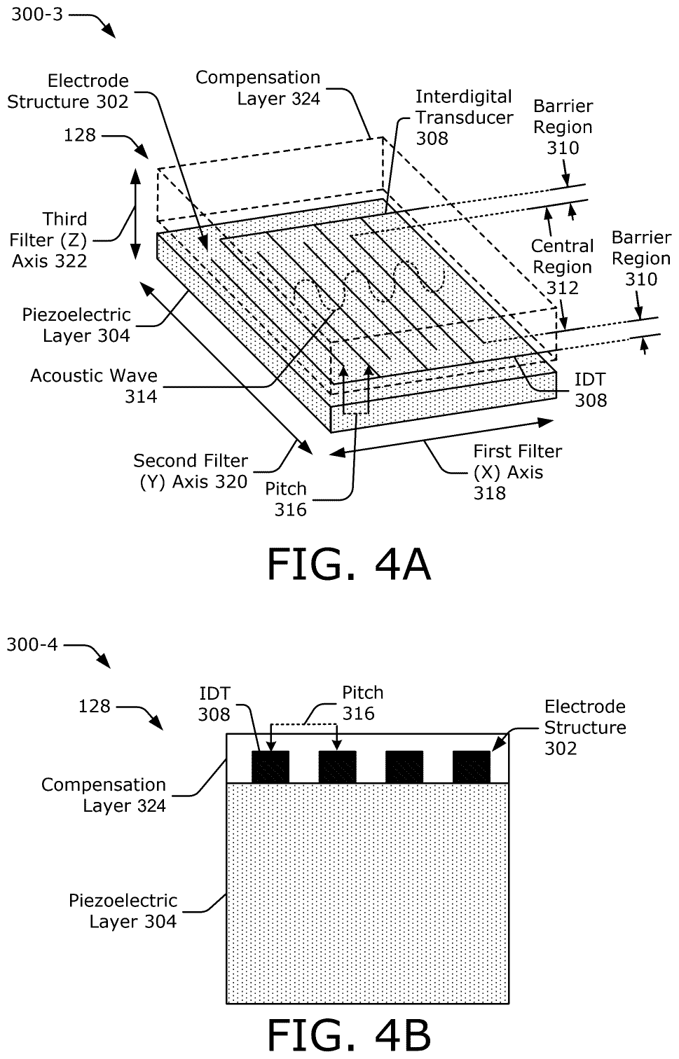

It should be appreciated that while a certain number of fingers are illustrated in FIGS. 3A, 3B, 4A, and 4B, the number of actual fingers and lengths and width of the fingers and busbars may be different in an actual implementation. Such parameters depend on the particular application and desired filter characteristics. In addition, the thin-film surface-acoustic-wave filter 126 can include multiple interconnected electrode structures each including multiple interdigital transducers 308 to achieve a desired passband (e.g., multiple interconnected resonators or interdigital transducers 308 in series or parallel connections to form a desired filter transfer function).

Although not shown, each reflector within the electrode structure 302 can have two busbars and a grating structure of conductive fingers that each connect to both busbars. In some implementations, the pitch of the reflector can be similar to or the same as the pitch 316 of the interdigital transducer 308 to reflect the acoustic wave 314 in the resonant frequency range.

In the three-dimensional perspective view 300-1, the thin-film surface-acoustic-wave filter 126 is defined by a first (X) axis 318, a second (Y) axis 320, and a third (Z) axis 322. The first axis 318 and the second axis 320 are parallel to a planar surface of the piezoelectric layer 304, and the second axis 320 is perpendicular to the first axis 318. The third axis 322 is normal (e.g., perpendicular) to the planar surface of the piezoelectric layer 304. The busbars of the interdigital transducer 308 are oriented to be parallel to the first axis 318. The fingers of the interdigital transducer 308 are orientated to be parallel to the second axis 320. Also, an orientation of the piezoelectric layer 304 causes an acoustic wave 314 to mainly form in a direction of the first axis 318. As such, the acoustic wave 314 forms in a direction that is substantially perpendicular to the direction of the fingers of the interdigital transducer 308. Another example type of surface-acoustic-wave filter 124 is further described with respect to FIGS. 4A and 4B.

FIGS. 4A and 4B illustrates an example implementation of the high-quality temperature-compensated surface-acoustic-wave filter 128 with site-selective piezoelectric-layer trimming. A three-dimensional perspective view 300-3 of the high-quality temperature-compensated surface-acoustic-wave filter 128 is shown in FIG. 4A, and a two-dimensional cross-section view 300-4 of the high-quality temperature-compensated surface-acoustic-wave filter 128 is shown in FIG. 4B.

The high-quality temperature-compensated surface-acoustic-wave filter 128 includes at least one electrode structure 302, at least one piezoelectric layer 304, and at least one compensation layer 324. The compensation layer 324 can provide temperature compensation to enable the high-quality temperature-compensated surface-acoustic-wave filter 128 to achieve a target temperature coefficient of frequency. In example implementations, the compensation layer 324 can be implemented using at least one silicon dioxide layer.

In the depicted configuration shown in the two-dimensional cross-section view 300-4, the electrode structure 302 is disposed between the piezoelectric layer 304 and the compensation layer 324. The piezoelectric layer 304 can form a substrate of the high-quality temperature-compensated surface-acoustic-wave filter 128.

The electrode structure 302 of the high-quality temperature-compensated surface-acoustic-wave filter 128 can be similar to the electrode structure 302 described above with respect to the thin-film surface-acoustic-wave filter 126 of FIG. 3-1. Likewise, the piezoelectric layer 304 of the high-quality temperature-compensated surface-acoustic-wave filter 128 can be similar to the piezoelectric layer 304 described above with respect to the thin-film surface-acoustic-wave filter 126 of FIG. 3-1. The piezoelectric layer 304 of the high-quality temperature-compensated surface-acoustic-wave filter 128, however, can be thicker than the piezoelectric layer 304 of the thin-film surface-acoustic-wave filter 126 of FIGS. 3A and 3B.

In the three-dimensional perspective view 300-1, the high-quality temperature-compensated surface-acoustic-wave filter 128 is defined by the first (X) axis 318, the second (Y) axis 320, and the third (Z) axis 322. The first axis 318 and the second axis 320 are parallel to a planar surface of the piezoelectric layer 304, and the second axis 320 is perpendicular to the first axis 318. The third axis 322 is normal (e.g., perpendicular) to the planar surface of the piezoelectric layer 304. The busbars of the interdigital transducer 308 are oriented to be parallel to the first axis 318. The fingers of the interdigital transducer 308 are orientated to be parallel to the second axis 320. Also, an orientation of the piezoelectric layer 304 causes an acoustic wave 314 to mainly form in a direction of the first axis 318. As such, the acoustic wave 314 forms in a direction that is substantially perpendicular to the direction of the fingers of the interdigital transducer 308.

Similar to the thin-film surface-acoustic-wave filter 126 of FIGS. 3A and 3B, the high-quality temperature-compensated surface-acoustic-wave filter 128 of FIGS. 4A and 4B can also include the barrier region 310 and the central region 312. The thin-film surface-acoustic-wave filter 126 and the high-quality temperature-compensated surface-acoustic-wave filter 128 can have similar operations, which are generally described below with respect to the surface-acoustic-wave filter 124.

During operation, the surface-acoustic-wave filter 124 (e.g., the thin-film surface-acoustic-wave filter 126 or the high-quality temperature-compensated surface-acoustic-wave filter 128) accepts a radio-frequency signal, such as the pre-filter transmit signal 224 or the pre-filter receive signal 230 shown in FIG. 2. The electrode structure 302 excites an acoustic wave 314 on the piezoelectric layer 304 using the inverse piezoelectric effect. For example, the interdigital transducer 308 in the electrode structure 302 generates an alternating electric field based on the accepted radio-frequency signal. The piezoelectric layer 304 enables the acoustic wave 314 to be formed in response to the alternating electric field generated by the interdigital transducer 308. In other words, the piezoelectric layer 304 causes, at least partially, the acoustic wave 314 to form responsive to electrical stimulation by one or more interdigital transducers 308.

The acoustic wave 314 propagates across the piezoelectric layer 304 and interacts with the interdigital transducer 308 or another interdigital transducer within the electrode structure 302 (not shown in FIG. 3A, 3B, 4A, or 4B). The acoustic wave 314 that propagates can be a standing wave. In some implementations, two reflectors within the electrode structure 302 cause the acoustic wave 314 to be formed as a standing wave across a portion of the piezoelectric layer 304. In other implementations, the acoustic wave 314 propagates across the piezoelectric layer 304 from the interdigital transducer 308 to another interdigital transducer (not shown).

Using the piezoelectric effect, the electrode structure 302 generates a filtered radio-frequency signal based on the propagated surface acoustic wave 314. In particular, the piezoelectric layer 304 generates an alternating electric field due to the mechanical stress generated by the propagation of the acoustic wave 314. The alternating electric field induces an alternating current in the other interdigital transducer or the interdigital transducer 308. This alternating current forms the filtered radio-frequency signal, which is provided at an output of the surface-acoustic-wave filter 124. The filtered radio-frequency signal can include the filtered transmit signal 226 or the filtered receive signal 232 of FIG. 2.

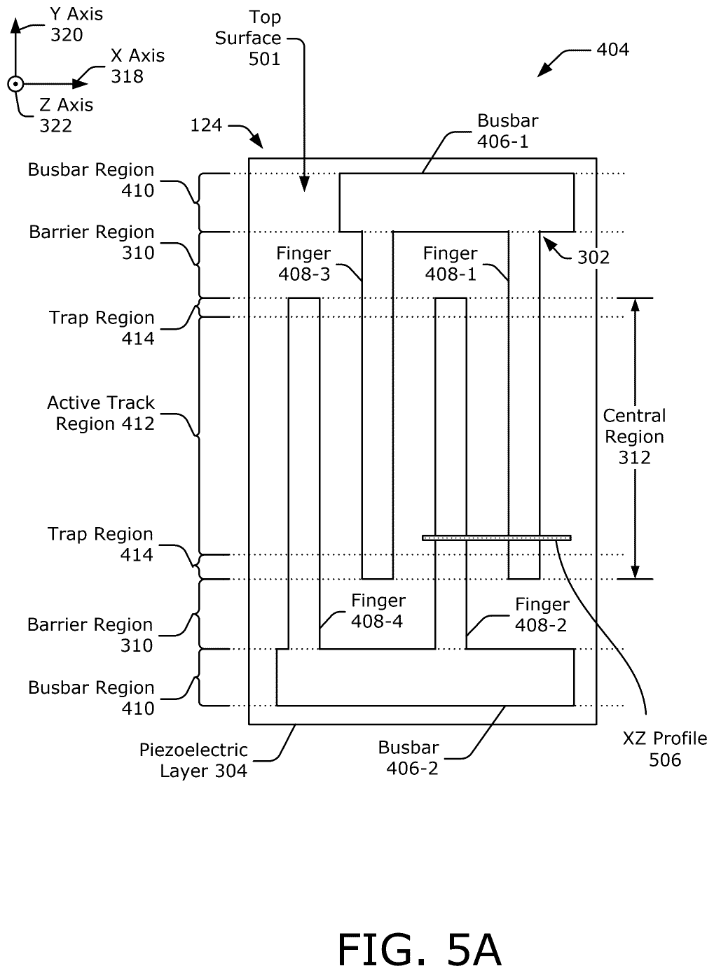

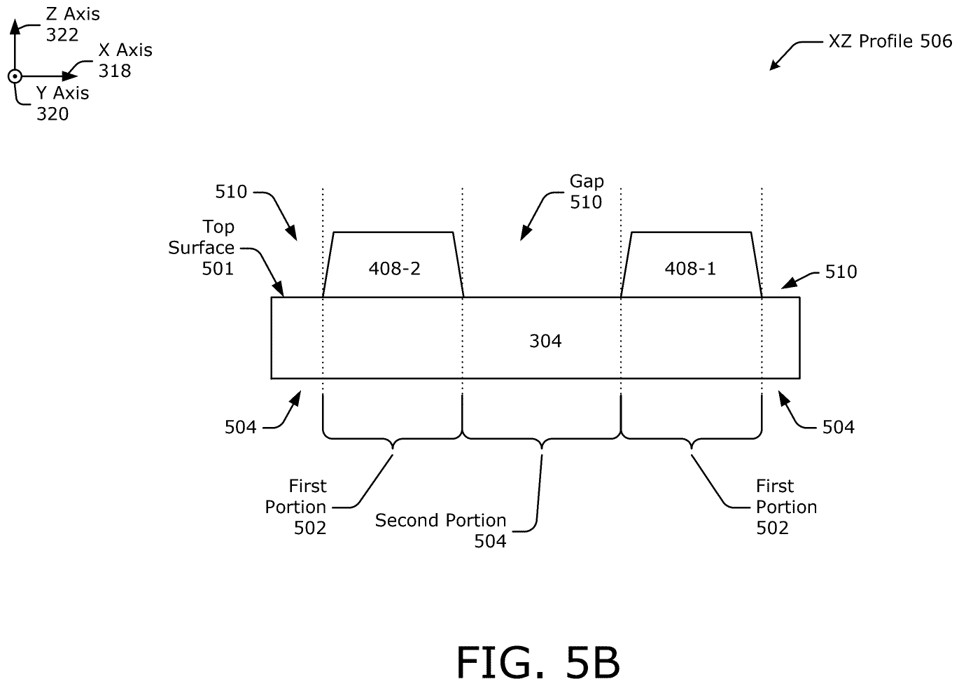

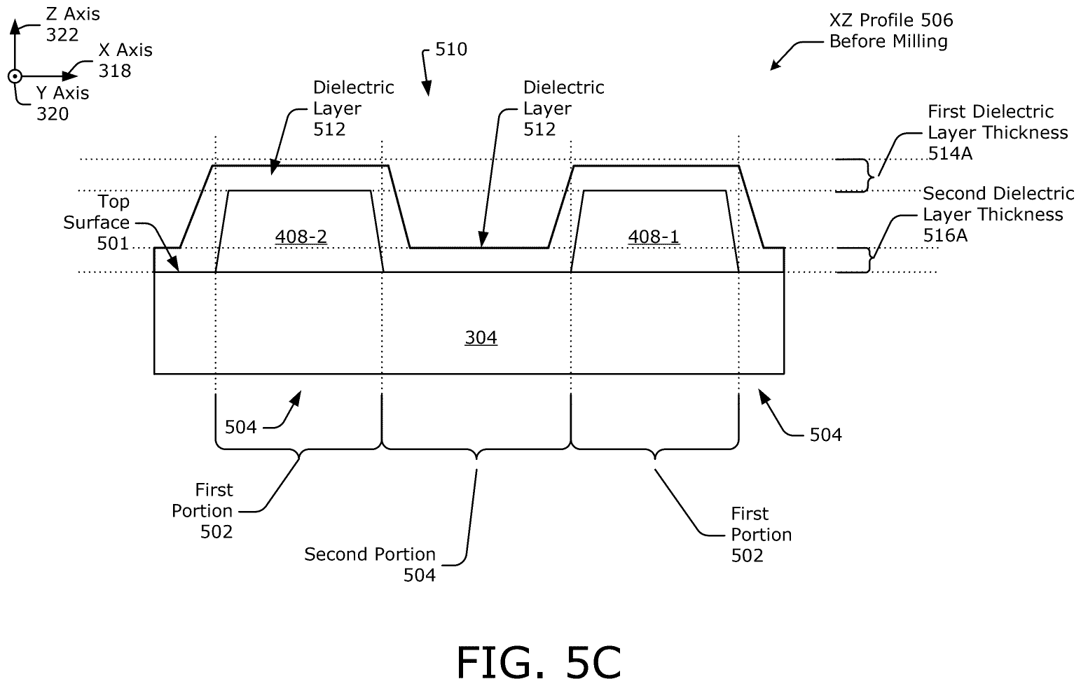

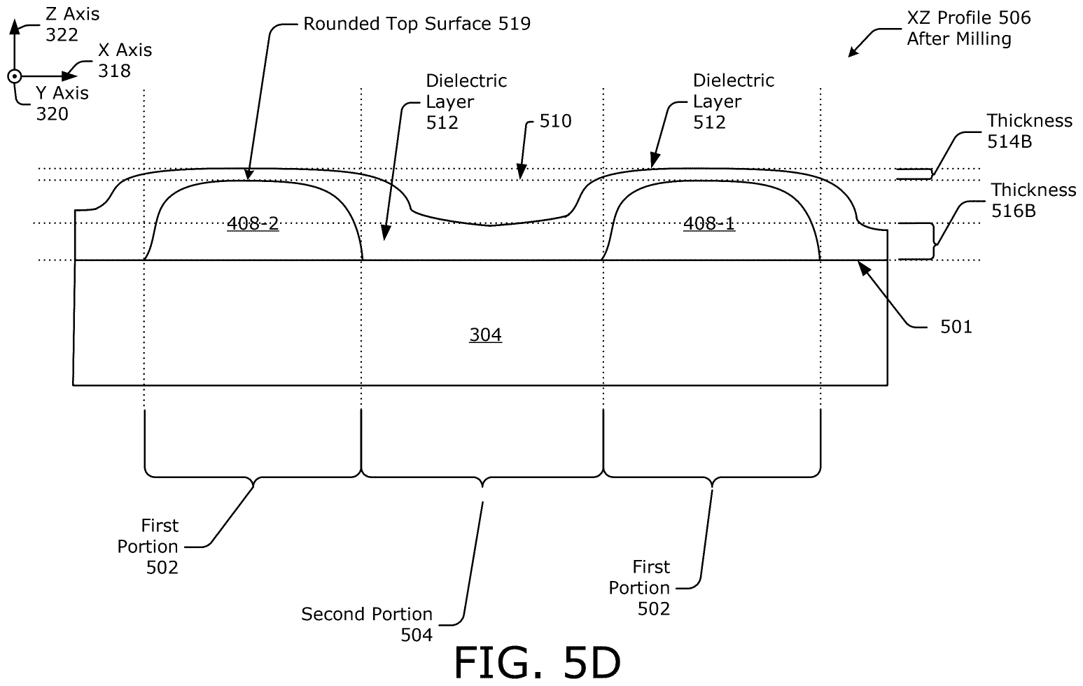

FIG. 5A illustrates aspects of the surface-acoustic-wave filter 124 with geometry tuning in accordance with aspects described herein. FIG. 5A illustrates a two-dimensional top-down view 404 of the surface-acoustic-wave filter 124. Further, as illustrated, the filter 124 includes a top surface of the piezoelectric layer, which will be covered by a dielectric layer that also covers the metallization layer used for the busbars 406-2 and 4-6-2, and the fingers 408-1 through 408-4. In the depicted configuration, the electrode structure 302 has a comb shape. Due to this comb shape, the fingers 408-1 to 408-4 are distributed across the first (X) axis 318 and have lengths along the second (Y) axis 320. This distribution causes consecutive pairs of fingers 408-1 to 408-4 to be separated across the first (X) axis 318. This separation forms gaps (e.g., openings) within the electrode structure 302. Such gaps are illustrated by XZ profile section 506, which is detailed further in FIGS. 5B-5D.

FIG. 5B illustrates aspects of the surface-acoustic-wave filter 124 with geometry tuning in accordance with aspects described herein. Within the central region 312 of FIG. 5A, there are gaps 510 between fingers 408-1 and 408-2, between fingers 408-2 and 408-3, and between fingers 408-3 and 408-4. The electrode structure 302 can also be considered to have gaps to the left of the finger 408-4 (as depicted in FIG. 5A) and to the right of the finger 408-1. The electrode structure 302 can further be considered to have gaps within the barrier region 310 and across portions of the busbar region 410 that are not occupied by the busbars 406-1 and 406-2.

FIG. 5B provides a detailed cross section in the XZ profile section 506, which illustrates fingers 408-1 and 408-2, with gaps 510 between the fingers and on each side of the fingers 408-1 and 408-2. Different portions of the piezoelectric layer 304 can be defined with respect to the electrode structure 302. A first portion 502 of the piezoelectric layer 304 is covered by the electrode structure 302. This first portion 502 (e.g., a covered portion) supports (e.g., physically supports) the electrode structure 302 and is positioned directly below (as shown in FIG. 5A) the electrode structure 302 along the third (Z) axis 322. In the two-dimensional top-down view 404 of the surface-acoustic-wave filter 124, the first portion 502 is not visible as it is underneath the electrode structure 302.

A second portion 504 of the piezoelectric layer 304 is exposed by the gaps within the electrode structure 302. The second portion 504 (e.g., an exposed portion) does not support (e.g., is not physically in direct contact with) the electrode structure 302 and is not positioned directly below the electrode structure 302. Within the central region 312, the second portion 504 exists between consecutive pairs of fingers 408-1 to 408-4. The second portion 504 also exists to the left of finger 408-4 and to the right of the finger 408-1. In the two-dimensional top-down view 404 of the surface-acoustic-wave filter 124, the second portion 504 of the piezoelectric layer 304 includes the surface of the piezoelectric layer 304 that is visible and not “hidden” by the electrode structure 302. The first and second portions 502 and 504 are also depicted in XZ profile section 506 of the surface-acoustic-wave filter 124.

FIG. 5C illustrates aspects of the surface-acoustic-wave filter 124 with geometry tuning in accordance with aspects described herein. As discussed above with respect to FIGS. 4A and 4B, a dielectric layer (e.g., the compensation layer 324) can be formed over the piezoelectric layer 304 and the electrode structure 302). FIG. 5C shows the dielectric layer 512 formed on the top surface 501 of the piezoelectric layer 304 and over the fingers 408-1 and 408-2. In some aspects, the dielectric layer 512 can be aluminum oxide (Al2O3). In other aspects, other materials can be used. In some aspects, a dielectric material can be selected based on stiffness characteristics, mass loading characteristics as related to an impact on electroacoustic performance, or other characteristics. Any material with characteristics suitable for an application that can be formed using atomic layer deposition can be used in some aspects. In some additional aspects, silicon nitride (Si3N4), hafnium oxide (HfO2), or yttrium oxide (Y2O3) can be used as the dielectric layer.

When initially fabricated (e.g., deposited via atomic layer deposition, etc.), a relatively even thickness of dielectric material is present both over the first portions 502 (e.g., over the fingers 408-2 and 408-1 of the metallization layer) and over the second portions 504 (e.g., in the gaps 510 directly on the surface of the piezoelectric layer 304). The areas near finger sidewalls may vary depending on the particular geometry of a given finger 408, but the general thickness of the dielectric layer 512 will be relatively constant before milling. The dielectric thickness includes a first dielectric layer thickness 514A over the first portions 502 of the piezoelectric layer 304, and a second dielectric layer thickness 516A over the second portions 504 of the piezoelectric layer 304.

FIG. 5D illustrates aspects of a piezoelectric device with geometry tuning in accordance with aspects described herein after a milling operation is applied. FIG. 5D illustrates the XZ profile section 506 after the milling operation, using the same x-axis 318, y-axis 320, and z-axis 322 orientation as in FIGS. 5A-5C. As illustrated in FIG. 5D, after milling, the top surfaces 519 of the fingers 408-1 and 408-2 are rounded due to the impact of the milling operation, and the dielectric layer 512 shifts so that the thickness 514B of the dielectric layer 512 in the first portion of the piezoelectric layer thins, and the thickness 516B of the dielectric layer 512 in the second portion 504 thickens. The change in thicknesses 514 and 516 results from the material on the top surface 519 of the fingers 408 shifting into the gaps 510 as part of the milling operation, resulting in the thickness 514B being thinner than the thickness 516. In various aspects, this results in a ratio of the dielectric layer on top of the electrode fingers to the thickness between the electrode fingers (e.g., a ratio of in-between electrode thickness to electrode top thickness or in in-between thickness value divided by a top thickness value) greater than one.

The milling operation can, for example, be argon (Ar) ion beam milling used on a wafer. Such operations can be used both for polishing materials (e.g., a plain substrate), and for milling (e.g., removing top layers of material) from a device that has undergone fabrication operations. Aspects described herein can be described in the context of an implementation where an Al2O3 dielectric is tuned (e.g., milled) using a milling process. In some aspects, the milling process uses a gas cluster ion beam (GCIB). In other aspects, other milling processes with similar behavior can be used. In some aspects, the milling process results in the thickness of layer 512 in region 512 being thicker than the thickness of region 512 over the electrodes (e.g., in the region 502) following the milling process.

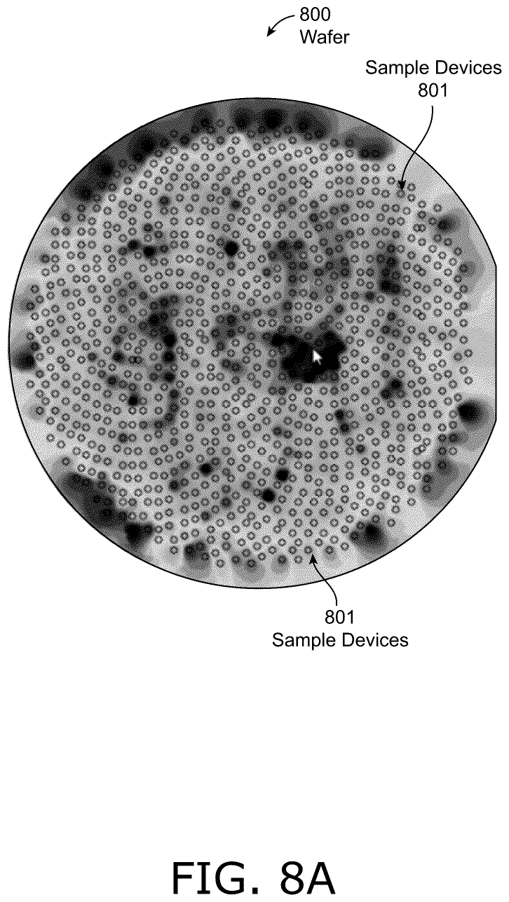

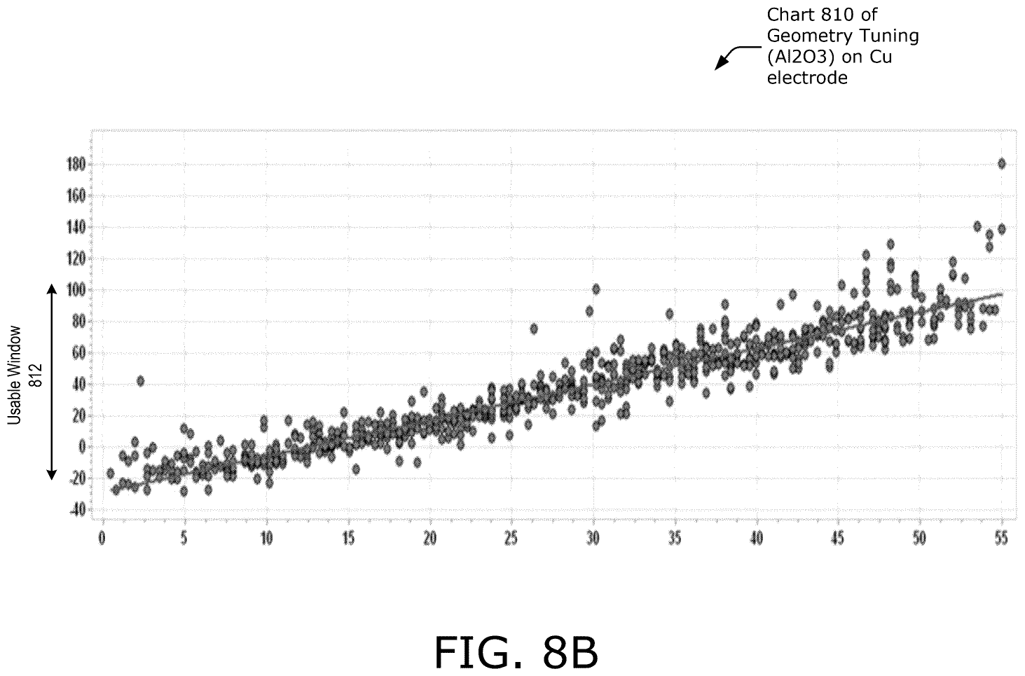

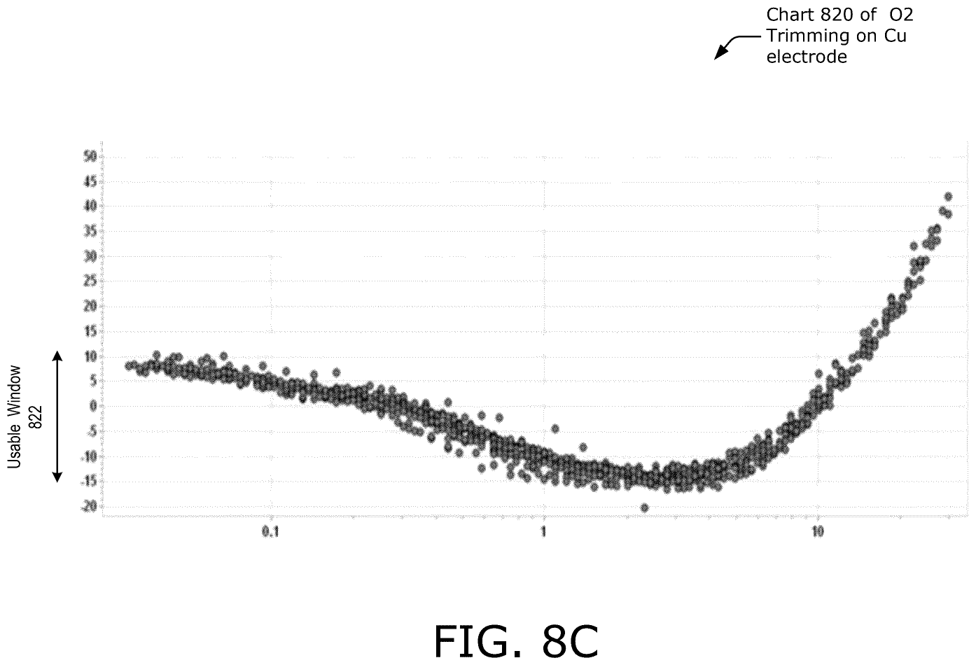

The illustrated shifting of the dielectric layer 512 and the rounding of the finger 408-1 and 408-2 top surfaces 519 result in a frequency shift in the operation of a device subjected to the milling operation. In some aspects, the milling process generates a frequency shift in a resonance of the SAW resonator being milled of at least 20 MHz. Additional details of the performance tuning are provided below, particularly with respect to FIGS. 8A-C.

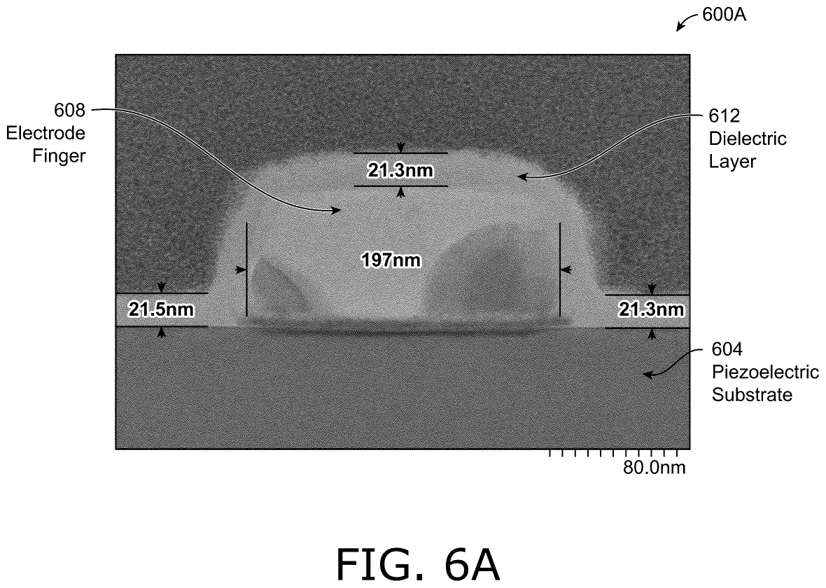

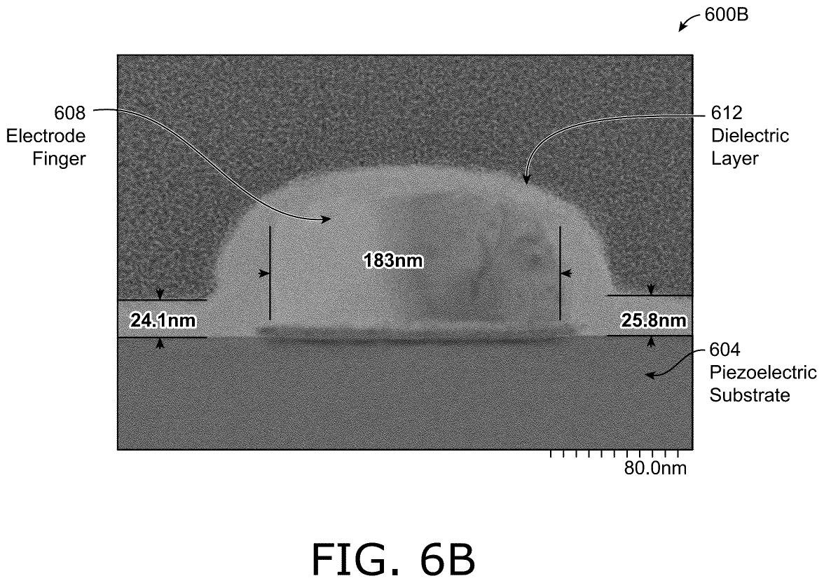

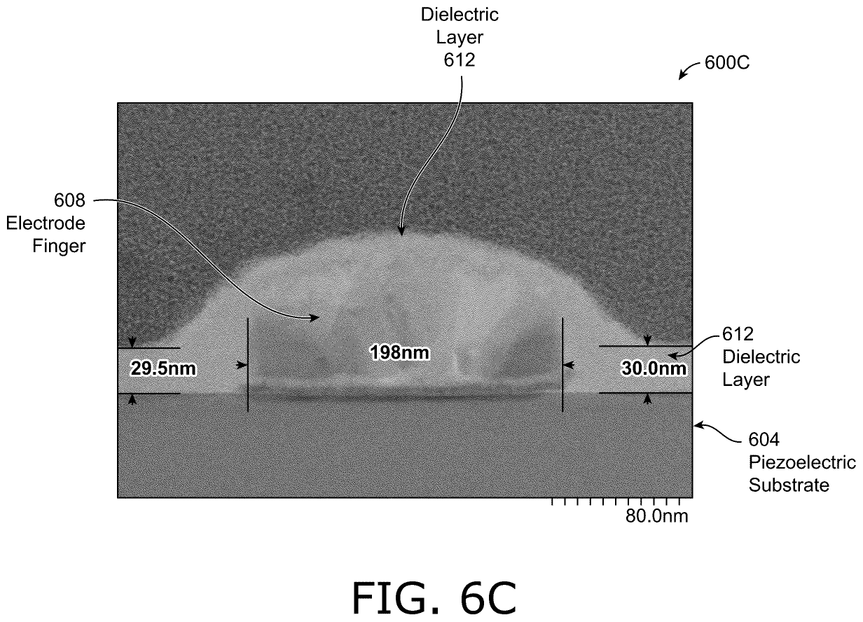

FIG. 6A illustrates aspects of a piezoelectric device 600A with geometry tuning in accordance with aspects described herein. FIG. 6A shows a piezoelectric substrate 604 with an electrode finger 608 covered by a dielectric layer 612 prior to a milling operation. As one example, the electrode finger 608 has a base width of approximately 200 nanometers (nm), and the dielectric layer 612 has a uniform thickness of approximately 21 nm. The dielectric layer 612 is Al2O3 as indicated above, and the milling process is an argon ion beam milling process.

FIG. 6B illustrates aspects of a piezoelectric device 600B with geometry tuning in accordance with aspects described herein. FIG. 6B shows the view of FIG. 6A after a moderate amount of milling, where a top of the electrode finger has rounded due to milling, the thickness of the dielectric layer 612 on the top surface of the electrode finger 608 has thinned, and the thickness of the dielectric layer 612 directly on the piezoelectric substrate 604 (e.g. in gaps between electrode fingers) has thickened (e.g., from approximately 21 nm to approximately 24-25 nm).

FIG. 6C illustrates aspects of a piezoelectric device 600C with geometry tuning in accordance with aspects described herein. FIG. 6B shows the view of FIGS. 6A and 6B after additional milling, where the top of the electrode finger has further rounded due to milling, the thickness of the dielectric layer 612 on the top surface of the electrode finger 608 has further thinned, and the thickness of the dielectric layer 612 directly on the piezoelectric substrate 604 (e.g. in gaps between electrode fingers) has thickened (e.g., to approximately 29-30 nm).

FIG. 7A illustrates aspects of a piezoelectric device 700A with geometry tuning in accordance with aspects described herein. As described above, as a milling operation is performed for longer dwell times (e.g., more bombardment on a specific area), the changes to the device are greater, including additional rounding on an electrode finger top surface, and additional shifting of the dielectric layer. FIGS. 7A-C show a closer view of the electrode finger 706, including the top surface 707, the sidewall 708, and the bottom surface 709, and illustrate additional details of the shift in the dielectric layer 712 near the sidewall 708 of the electrode finger, corresponding to the milling durations shown in FIGS. 6A-C.

In FIG. 7A, the piezoelectric device 700A is subjected to little or no milling, and the thickness of the dielectric layer in contact with the piezoelectric substrate 704 remains relatively constant (e.g., approximately 20-21 nm) along the electrode finger sidewall 708 and on the electrode finger top surface 707 (not shown in FIG. 7A).

FIG. 7B illustrates aspects of a piezoelectric device 700B with geometry tuning in accordance with aspects described herein. With moderate milling, the piezoelectric device 700B has an electrode finger 706 where the electrode finger top surface begins to round, the dielectric layer 712 thickness on the top surface 707 of the electrode begins to thin (e.g., to approximately 17 nm), and the dielectric layer 712 thickness in the bap on the surface of the piezoelectric substrate thickens (e.g., to approximately 24 nm). Additionally, as illustrated, the thickness of the dielectric layer 712 along the sidewall 708 of the electrode finger 706 accumulates additional dielectric material as the material from the top surface 707 shifts toward the gap area. As illustrated in FIG. 7B, this results in an accumulation area near the sidewall with a thickness greater than in other areas, so that the thickness of the dielectric from the top surface 707 to the bottom surface 709 of the dielectric layer 712 increases, and is greatest near the bottom surface 709 near the sidewall 708. The thickness along the sidewall 708 near the bottom surface 709 is the greatest, and then is thinner near the center of the gap between electrode fingers. In the illustrated example, with moderate milling as in FIG. 7B, the top surface thickness is approximately 17 nm, increasing to 25 nm, then 32 nm, then 35 nm at the bottom surface 709 along the sidewall 708, then decreasing to 24 nm in the gap away from the sidewall 708.

FIG. 7C illustrates aspects of a piezoelectric device 700C with geometry tuning in accordance with aspects described herein. The thickness variation described above increases further as a result of additional milling as illustrated in FIG. 7C. In FIG. 7C, the dielectric layer 712 thickness on the top surface 707 of the electrode finger is approximately 13 nm. The thickness increases along the sidewall 708 to 25 nm, 33 nm, and 47 nm from the top surface to the bottom surface. The thickness of the dielectric layer 712 decreases away from the bottom surface 709 near the sidewall toward the center of the gap between fingers, reducing to approximately 29 nm. As seen by the difference between FIGS. 7B and 7C, the thickness of the dielectric layer 712 increases in the gap (e.g., from 24 nm to 29 nm), and the increased thickness near the sidewall 708 expands away from the sidewall, while the thickness on the top surface 707 further thins. Such shifts in the geometry of the dielectric layer 712 further tunes the frequency performance of the piezoelectric device 700 along with the rounding of the top surface 707 of the electrode finger 706, allowing the tuned device performance to match targeted operation characteristics for a particular implementation.

The increased thickness of the dielectric layer 712 near the sidewalls can result in the dielectric layer forming curved a bowl shape between adjacent electrode fingers, where one side of the bowl shape is the increased thickness of the dielectric layer 712 against a sidewall of a first electrode finger, and the other side of the bowl shape is the increased thickness of the dielectric layer against a facing sidewall of a second electrode finger that is adjacent to the first electrode finger.

FIG. 8A illustrates aspects of a wafer 800 including piezoelectric devices that can be tested and tuned using geometry tuning in accordance with aspects described herein. As indicated above, electroacoustic devices can be fabricated on a wafer with many other devices. After the initial fabrication of the wafer 800, including fabrication of a piezoelectric layer, a metallization layer, and a covering dielectric, sample devices 801 can be tested in a pattern over the surface of the wafer 800. The sample values can be used in milling the devices by varying the dwell time of the milling operation, allowing for greater milling for devices needing a greater shift (e.g., with a greater dwell time resulting in devices with structures similar to FIGS. 6C and 7C, intermediate dwell time resulting in devices similar to FIGS. 6B and 7B, and little to no dwell time resulting in devices similar to FIGS. 6A and 7A.) In some aspects, this milling process is a gas cluster ion beam milling process, and the dwell time in at least a portion of the wafer is selected to generate a frequency shift in a resonance of the SAW resonators in the portion of the wafer that is greater than 20 MHz. Different dwell times can be selected for different areas of the wafer to shift the resonance frequencies in the different areas based on the clusters of sampled operating frequencies or frequency values for the sample devices 801 based on test values for the sample devices 801.

FIG. 8B illustrates a performance chart 810 of piezoelectric devices tuned using geometry tuning in accordance with aspects described herein. The performance chart 810 has a y-axis showing a frequency shift in megahertz (MHz) and the x-axis illustrates the dwell time of a milling operation in seconds per meter (s/m) used to achieve the illustrated frequency shift reflected by the y position of sample devices in a wafer.

FIG. 8C illustrates a performance chart 820 of piezoelectric devices tuned using prior oxygen trimming tuning for comparison with the performance chart of FIG. 8B illustrating performance of piezoelectric devices tuned using geometry tuning in accordance with aspects described herein. As described above, oxygen trimming is a previously known method for tuning electroacoustic devices. Oxygen trimming involves shooting an ion beam of O2 at a top surface of a wafer to remove material from the top surface. Such an operation can result in an oxidation of the metallization layer, destruction of the piezoelectric operation at the surface of the piezoelectric layer, resulting in a frequency shift. Such frequency shifts, however, are lower than what is possible using the milling operations described above, and for higher frequency shifts, can result in device failure (e.g., due to damage to electrode fingers and/or piezoelectric effect operation failure if too much of the substrate is damaged).

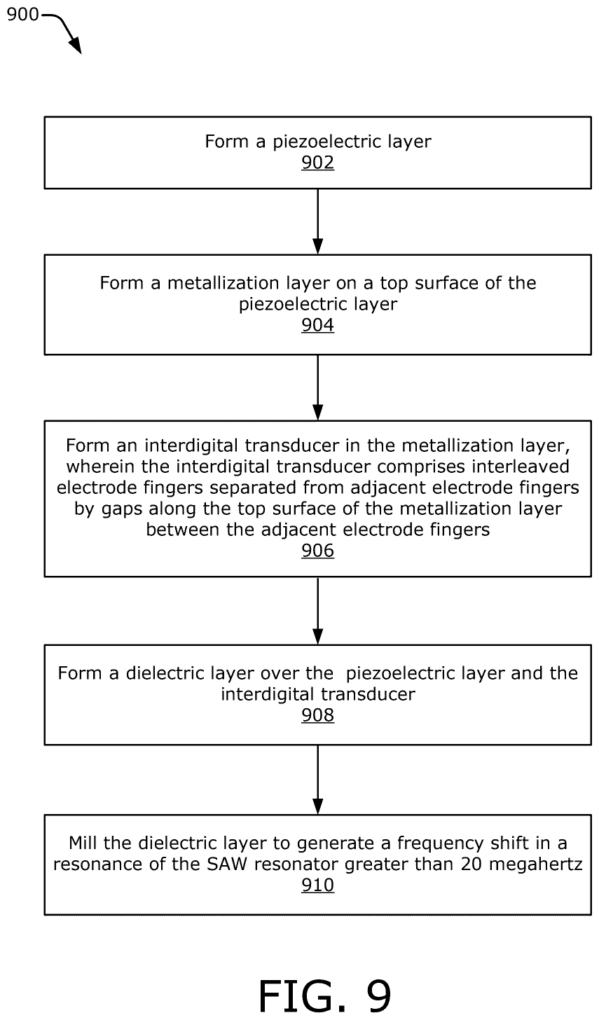

FIG. 9 is a flow diagram illustrating an example process for manufacturing a surface-acoustic-wave filter using geometry tuning in accordance with aspects described herein.

FIG. 9 is a flow diagram illustrating an example process 900 for manufacturing an electroacoustic device such as the surface-acoustic-wave filter 124.

The process 900 includes block 902, which involves forming a piezoelectric layer.

The process 900 includes block 904, which involves forming a metallization layer on a top surface of the piezoelectric layer.

The process 900 includes block 906, which involves forming an interdigital transducer in the metallization layer, wherein the interdigital transducer comprises interleaved electrode fingers separated from adjacent electrode fingers by gaps along the top surface of the metallization layer between the adjacent electrode fingers.

The process 900 includes block 908, which involves forming a dielectric layer over the piezoelectric layer and the interdigital transducer.

The process 900 includes block 910, which involves milling the dielectric layer to generate a frequency shift in a resonance of the SAW resonator greater than 20 megahertz (MHz).

Additional aspects can include repeated or intervening operations in addition to those illustrated by the process 900 of FIG. 9, including, but not limited to, operations in accordance with any aspect described herein.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). Further, items represented in the accompanying figures and terms discussed herein may be indicative of one or more items or terms, and thus reference may be made interchangeably to single or plural forms of the items and terms in this written description. Finally, although subject matter has been described in language specific to structural features or methodological operations, it is to be understood that the subject matter defined in the appended claims is not necessarily limited to the specific features or operations described above, including not necessarily being limited to the organizations in which features are arranged or the orders in which operations are performed.

The term “substantially,” in reference to a given parameter, property, or condition, may refer to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

Aspects of the present disclosure are applicable to any suitable electronic device (such as security systems, smartphones, tablets, laptop computers, vehicles, drones, or other devices) including or coupled to one or more active depth sensing systems. In some aspects, light detection and ranging (LiDAR) functionality of any such device can be implemented using aspects described herein. While described below with respect to a device having or coupled to one light projector, aspects of the present disclosure are applicable to devices having any number of light projectors and are therefore not limited to specific devices.

The term “device” is not limited to one or a specific number of physical objects (such as one smartphone, one controller, one processing system and so on). As used herein, a device may be any electronic device with one or more parts that may implement at least some portions of this disclosure. While the below description and examples use the term “device” to describe various aspects of this disclosure, the term “device” is not limited to a specific configuration, type, or number of objects. Additionally, the term “system” is not limited to multiple components or specific aspects. For example, a system may be implemented on one or more printed circuit boards or other substrates and may have movable or static components. While the below description and examples use the term “system” to describe various aspects of this disclosure, the term “system” is not limited to a specific configuration, type, or number of objects.

Specific details are provided in the description above to provide a thorough understanding of the aspects and examples provided herein. However, it will be understood by one of ordinary skill in the art that the aspects may be practiced without these specific details. For clarity of explanation, in some instances the present technology may be presented as including individual functional blocks including functional blocks including devices, device components, steps or routines in a method embodied in software, or combinations of hardware and software. Additional components may be used other than those shown in the figures and/or described herein. For example, circuits, systems, networks, processes, and other components may be shown as components in block diagram form in order not to obscure the aspects in unnecessary detail. In other instances, well-known circuits, processes, algorithms, structures, and techniques may be shown without unnecessary detail in order to avoid obscuring the aspects.

Individual aspects may be described above as a process or method which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination can correspond to a return of the function to the calling function or the main function.

Processes and methods according to the above-described examples can be implemented using computer-executable instructions that are stored or otherwise available from computer-readable media. Such instructions can include, for example, instructions and data which cause or otherwise configure a general-purpose computer, special purpose computer, or a processing device to perform a certain function or group of functions. Portions of computer resources used can be accessible over a network. The computer executable instructions may be, for example, binaries, intermediate format instructions such as assembly language, firmware, source code, etc.

The term “computer-readable medium” includes, but is not limited to, portable or non-portable storage devices, optical storage devices, and various other mediums capable of storing, containing, or carrying instruction(s) and/or data. A computer-readable medium may include a non-transitory medium in which data can be stored and that does not include carrier waves and/or transitory electronic signals propagating wirelessly or over wired connections. Examples of a non-transitory medium may include, but are not limited to, a magnetic disk or tape, optical storage media such as compact disk (CD) or digital versatile disk (DVD), flash memory, magnetic or optical disks, USB devices provided with non-volatile memory, networked storage devices, any suitable combination thereof, among others. A computer-readable medium may have stored thereon code and/or machine-executable instructions that may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, or the like.

In some aspects the computer-readable storage devices, mediums, and memories can include a cable or wireless signal containing a bit stream and the like. However, when mentioned, non-transitory computer-readable storage media expressly exclude media such as energy, carrier signals, electromagnetic waves, and signals per se.

Devices implementing processes and methods according to these disclosures can include hardware, software, firmware, middleware, microcode, hardware description languages, or any combination thereof, and can take any of a variety of form factors. When implemented in software, firmware, middleware, or microcode, the program code or code segments to perform the necessary tasks (e.g., a computer-program product) may be stored in a computer-readable or machine-readable medium. A processor(s) may perform the necessary tasks. Typical examples of form factors include laptops, smart phones, mobile phones, tablet devices or other small form factor personal computers, personal digital assistants, rackmount devices, standalone devices, and so on. Functionality described herein also can be embodied in peripherals or add-in cards. Such functionality can also be implemented on a circuit board among different chips or different processes executing in a single device, by way of further example.

The instructions, media for conveying such instructions, computing resources for executing them, and other structures for supporting such computing resources are example means for providing the functions described in the disclosure.

In the foregoing description, aspects of the application are described with reference to specific aspects thereof, but those skilled in the art will recognize that the application is not limited thereto. Thus, while illustrative aspects of the application have been described in detail herein, it is to be understood that the inventive concepts may be otherwise variously embodied and employed, and that the appended claims are intended to be construed to include such variations, except as limited by the prior art. Various features and aspects of the above-described application may be used individually or jointly. Further, aspects can be utilized in any number of environments and applications beyond those described herein without departing from the broader spirit and scope of the specification. The specification and drawings are, accordingly, to be regarded as illustrative rather than restrictive. For the purposes of illustration, methods were described in a particular order. It should be appreciated that in alternate aspects, the methods may be performed in a different order than that described.

One of ordinary skill will appreciate that the less than (“<”) and greater than (“>”) symbols or terminology used herein can be replaced with less than or equal to (“s”) and greater than or equal to (“>”) symbols, respectively, without departing from the scope of this description.

Where components are described as being “configured to” perform certain operations, such configuration can be accomplished, for example, by designing electronic circuits or other hardware to perform the operation, by programming programmable electronic circuits (e.g., microprocessors, or other suitable electronic circuits) to perform the operation, or any combination thereof.

The phrase “coupled to” refers to any component that is physically connected to another component either directly or indirectly, and/or any component that is in communication with another component (e.g., connected to the other component over a wired or wireless connection, and/or other suitable communication interface) either directly or indirectly.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, A and B and C, or any duplicate information or data (e.g., A and A, B and B, C and C, A and A and B, and so on), or any other ordering, duplication, or combination of A, B, and C. The language “at least one of” a set and/or “one or more” of a set does not limit the set to the items listed in the set. For example, claim language reciting “at least one of A and B” or “at least one of A or B” may mean A, B, or A and B, and may additionally include items not listed in the set of A and B. The phrases “at least one” and “one or more” are used interchangeably herein.

Claim language or other language reciting “at least one processor configured to,” “at least one processor being configured to,” “one or more processors configured to,” “one or more processors being configured to,” or the like indicates that one processor or multiple processors (in any combination) can perform the associated operation(s). For example, claim language reciting “at least one processor configured to: X, Y, and Z” means a single processor can be used to perform operations X, Y, and Z; or that multiple processors are each tasked with a certain subset of operations X, Y, and Z such that together the multiple processors perform X, Y, and Z; or that a group of multiple processors work together to perform operations X, Y, and Z. In another example, claim language reciting “at least one processor configured to: X, Y, and Z” can mean that any single processor may only perform at least a subset of operations X, Y, and Z.

Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions.

Where reference is made to an entity (e.g., any entity or device described herein) performing functions or being configured to perform functions (e.g., steps of a method), the entity may be configured to cause one or more elements (individually or collectively) to perform the functions. The one or more components of the entity may include at least one memory, at least one processor, at least one communication interface, another component configured to perform one or more (or all) of the functions, and/or any combination thereof. Where reference to the entity performing functions, the entity may be configured to cause one component to perform all functions, or to cause more than one component to collectively perform the functions. When the entity is configured to cause more than one component to collectively perform the functions, each function need not be performed by each of those components (e.g., different functions may be performed by different components) and/or each function need not be performed in whole by only one component (e.g., different components may perform different sub-functions of a function).

The various illustrative logical blocks, modules, circuits, and algorithm steps described in connection with the aspects disclosed herein may be implemented as electronic hardware, computer software, firmware, or combinations thereof. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present application.

The techniques described herein may also be implemented in electronic hardware, computer software, firmware, or any combination thereof. Such techniques may be implemented in any of a variety of devices such as general-purposes computers, wireless communication device handsets, or integrated circuit devices having multiple uses including application in wireless communication device handsets and other devices. Any features described as modules or components may be implemented together in an integrated logic device or separately as discrete but interoperable logic devices. If implemented in software, the techniques may be realized at least in part by a computer-readable data storage medium including program code including instructions that, when executed, performs one or more of the methods described above. The computer-readable data storage medium may form part of a computer program product, which may include packaging materials. The computer-readable medium may include memory or data storage media, such as random-access memory (RAM) such as synchronous dynamic random-access memory (SDRAM), read-only memory (ROM), non-volatile random-access memory (NVRAM), electrically erasable programmable read-only memory (EEPROM), Flash memory, magnetic or optical data storage media, and the like. The techniques additionally, or alternatively, may be realized at least in part by a computer-readable communication medium that carries or communicates program code in the form of instructions or data structures and that can be accessed, read, and/or executed by a computer, such as propagated signals or waves.

The program code may be executed by a processor, which may include one or more processors, such as one or more digital signal processors (DSPs), general-purpose microprocessors, an application specific integrated circuits (ASICs), field programmable logic arrays (FPGAs), or other equivalent integrated or discrete logic circuitry. Such a processor may be configured to perform any of the techniques described in this disclosure. A general-purpose processor may be a microprocessor; but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration). Accordingly, the term “processor,” as used herein may refer to any of the foregoing structure, any combination of the foregoing structure, or any other structure or apparatus suitable for implementation of the techniques described herein.

Some aspects are described below.

Aspect 1. An electroacoustic apparatus comprising: a piezoelectric layer; a metallization layer comprising an interdigital transducer formed on a top surface of the piezoelectric layer, wherein the interdigital transducer comprises interleaved electrode fingers; and a dielectric layer formed over the piezoelectric layer and the metallization layer, wherein a first dielectric layer thickness over top surfaces of the interleaved electrode fingers is thinner than a second dielectric layer thickness over the piezoelectric layer between adjacent electrode fingers of the interleaved electrode fingers.

Aspect 2. The electroacoustic apparatus of Aspect 1, wherein the dielectric layer comprises Aluminum Oxide (Al2O3).

Aspect 3. The electroacoustic apparatus of Aspect 1, wherein the dielectric layer comprises silicon nitride Silicon Nitride (Si3N4).

Aspect 4. The electroacoustic apparatus of any of Aspects 1 through 3, wherein the top surfaces are rounded such that the interleaved electrode fingers each have rounded top surfaces opposite the top surface of the piezoelectric layer.

Aspect 5. The electroacoustic apparatus of any of Aspects 1 through 4, wherein the dielectric layer is formed using atomic layer deposition.

Aspect 6. The electroacoustic apparatus of any of Aspects 1 through 5, wherein the electroacoustic apparatus is a resonator within a wireless communication filter.

Aspect 7. The electroacoustic apparatus of any of Aspects 1 through 6, further comprising control circuitry and an antenna coupled to the interdigital transducer for wireless communications.

Aspect 8. The electroacoustic apparatus of any of Aspects 1 through 7, wherein a ratio of the second dielectric layer thickness to the first dielectric layer thickness is greater than one.

Aspect 9. The electroacoustic apparatus of any of Aspects 1 through 8, wherein the dielectric layer forms a curved bowl shape between the first electrode finger and the second electrode layer.

Aspect 10. An electroacoustic device comprising: a piezoelectric layer having a top surface; a first electrode finger having a bottom surface on the top surface of the piezoelectric layer, a top surface opposite the top surface of the piezoelectric layer, and first electrode sidewalls; a second electrode finger parallel to the first electrode finger having a bottom surface on the top surface of the piezoelectric layer, a top surface opposite the top surface of the piezoelectric layer, and second electrode sidewalls; and a dielectric layer formed over the piezoelectric layer, the first electrode finger, and the second electrode finger, wherein a first dielectric layer thickness over the top surface of the first electrode finger is less than a second dielectric layer thickness over the piezoelectric layer between the first electrode finger and the second electrode finger, and wherein a sidewall thickness of the dielectric layer along a first sidewall of the first electrode finger increases along the first sidewall from the top surface to the bottom surface of the first electrode finger.

Aspect 11. The electroacoustic device of Aspect 10, wherein the top surface of the first electrode finger and the top surface of the second electrode finger have a rounded top from a milling process.

Aspect 12. The electroacoustic device of any of Aspects 10 through 11, wherein the dielectric layer forms a curved bowl shape between the first electrode finger and the second electrode layer.

Aspect 13. The electroacoustic device of any of Aspects 10 through 12, wherein the milling process is a gas cluster ion beam milling process.

Aspect 14. The electroacoustic device of any of Aspects 10 through 13, wherein the dielectric layer is formed as a uniform thickness dielectric layer which is adjusted via milling to generate the first dielectric layer thickness and the second dielectric layer thickness.

Aspect 15. The electroacoustic device of any of Aspects 10 through 14, wherein the dielectric layer comprises hafnium oxide (HfO2).

Aspect 16. The electroacoustic device of any of Aspects 10 through 14, wherein the dielectric layer comprises yttrium oxide (Y2O3).

Aspect 17. The electroacoustic device of any of Aspects 10 through 16, wherein a sidewall thickness of the dielectric layer at the bottom surface of the first electrode finger is greater than the second dielectric layer thickness.

Aspect 18. A method of manufacturing a surface acoustic wave (SAW) resonator, the method comprising: forming a piezoelectric layer; forming a metallization layer on a top surface of the metallization layer; forming an interdigital transducer in the metallization layer, wherein the interdigital transducer comprises interleaved electrode fingers separated from adjacent electrode fingers by gaps along the top surface of the metallization layer between the adjacent electrode fingers; forming a dielectric layer over the piezoelectric layer and the interdigital transducer; and milling the dielectric layer to generate a frequency shift in a resonance of the SAW resonator greater than 20 megahertz (MHz).

Aspect 19. The method of Aspect 18, further comprising: forming the piezoelectric layer, the interdigital transducer, and the dielectric layer as part of a wafer comprising a plurality of SAW resonators; sampling operating frequencies of the plurality of SAW resonators in different positions on the wafer; wherein milling comprises a gas cluster ion beam milling process performed on the wafer based on the sampled operating frequencies to determine milling dwell times matched to the different positions on the wafer; and separating the wafer into different devices.

Aspect 20. The method of Aspect 18, wherein top surfaces of the interleaved electrode fingers have a rounded top from a milling process, wherein the dielectric layer forms a curved bowl shape between the adjacent electrode fingers from the milling process, and wherein a ratio of a second dielectric layer thickness between the adjacent electrode finger to a first dielectric layer thickness on the top surfaces is greater than one due to the milling process.

Aspect 21. An apparatus comprising means for generating an electroacoustic resonance in accordance with any aspect described above.

Aspect 22. An apparatus in accordance with any aspect described above integrated into a wireless communication device comprising an antenna and an interface.

What is claimed is:

1. An electroacoustic apparatus comprising:
a piezoelectric layer;
a metallization layer comprising an interdigital transducer formed on a top surface of the piezoelectric layer, wherein the interdigital transducer comprises interleaved electrode fingers; and
a dielectric layer formed over the piezoelectric layer and the metallization layer, wherein a first dielectric layer thickness over top surfaces of the interleaved electrode fingers is thinner than a second dielectric layer thickness over the piezoelectric layer between adjacent electrode fingers of the interleaved electrode fingers.

2. The electroacoustic apparatus of claim 1, wherein the dielectric layer comprises Aluminum Oxide (Al2O3).

3. The electroacoustic apparatus of claim 1, wherein the dielectric layer comprises silicon nitride Silicon Nitride (Si3N4).

4. The electroacoustic apparatus of claim 1, wherein the top surfaces are rounded such that the interleaved electrode fingers each have rounded top surfaces opposite the top surface of the piezoelectric layer.

5. The electroacoustic apparatus of claim 1, wherein the dielectric layer is formed using atomic layer deposition.

6. The electroacoustic apparatus of claim 1, wherein the electroacoustic apparatus is a resonator within a wireless communication filter.

7. The electroacoustic apparatus of claim 1, further comprising control circuitry and an antenna coupled to the interdigital transducer for wireless communications.

8. The electroacoustic apparatus of claim 1, wherein a ratio of the second dielectric layer thickness to the first dielectric layer thickness is greater than one.

9. The electroacoustic apparatus of claim 1, wherein the dielectric layer forms a curved bowl shape between the adjacent electrode fingers.

10. An electroacoustic device comprising:
a piezoelectric layer having a top surface;
a first electrode finger having a bottom surface on the top surface of the piezoelectric layer, a top surface opposite the top surface of the piezoelectric layer, and first electrode sidewalls;
a second electrode finger parallel to the first electrode finger having a bottom surface on the top surface of the piezoelectric layer, a top surface opposite the top surface of the piezoelectric layer, and second electrode sidewalls; and
a dielectric layer formed over the piezoelectric layer, the first electrode finger, and the second electrode finger, wherein a first dielectric layer thickness over the top surface of the first electrode finger is less than a second dielectric layer thickness over the piezoelectric layer between the first electrode finger and the second electrode finger, and wherein a sidewall thickness of the dielectric layer along a first sidewall of the first electrode finger increases along the first sidewall from the top surface to the bottom surface of the first electrode finger.

11. The electroacoustic device of claim 10, wherein the top surface of the first electrode finger and the top surface of the second electrode finger have a rounded top from a milling process.

12. The electroacoustic device of claim 11, wherein the dielectric layer forms a curved bowl shape between the first electrode finger and the second electrode finger.

13. The electroacoustic device of claim 12, wherein the milling process is a gas cluster ion beam milling process.

14. The electroacoustic device of claim 10, wherein the dielectric layer is formed as a uniform thickness dielectric layer which is adjusted via milling to generate the first dielectric layer thickness and the second dielectric layer thickness.

15. The electroacoustic device of claim 10, wherein the dielectric layer comprises hafnium oxide (HfO2).

16. The electroacoustic device of claim 10, wherein the dielectric layer comprises yttrium oxide (Y2O3).

17. The electroacoustic device of claim 10, wherein a sidewall thickness of the dielectric layer at the bottom surface of the first electrode finger is greater than the second dielectric layer thickness.

18. A method of manufacturing a surface acoustic wave (SAW) resonator, the method comprising:
forming a piezoelectric layer;
forming a metallization layer on a top surface of the piezoelectric layer;
forming an interdigital transducer in the metallization layer, wherein the interdigital transducer comprises interleaved electrode fingers separated from adjacent electrode fingers by gaps along the top surface of the metallization layer between the adjacent electrode fingers;
forming a dielectric layer over the piezoelectric layer and the interdigital transducer; and
milling the dielectric layer to generate a frequency shift in a resonance of the SAW resonator greater than 20 megahertz (MHz).

19. The method of claim 18, further comprising:
forming the piezoelectric layer, the interdigital transducer, and the dielectric layer as part of a wafer comprising a plurality of SAW resonators;
sampling operating frequencies of the plurality of SAW resonators in different positions on the wafer;
wherein milling comprises a gas cluster ion beam milling process performed on the wafer based on the sampled operating frequencies to determine milling dwell times matched to the different positions on the wafer; and
separating the wafer into different devices.

20. The method of claim 18, wherein top surfaces of the interleaved electrode fingers have a rounded top from a milling process, wherein the dielectric layer forms a curved bowl shape between the adjacent electrode fingers from the milling process, and wherein a ratio of a second dielectric layer thickness between the adjacent electrode fingers to a first dielectric layer thickness on the top surfaces is greater than one due to the milling process.
